(19) United States
(12) Patent Application Publication
(10) Pub. No.: US 2026/0150340 A1
(43) Pub. Date: May 28, 2026

(54) FORK SHEET DEVICE

(71) Applicant: INTERNATIONAL BUSINESS MACHINES CORPORATION, Armonk, NY (US)

(72) Inventors: Minhaz Abedin, Delmar, NY (US); SHRAVAN KUMAR MATHAM, Albany, NY (US); Ruilong Xie, Niskayuna, NY (US); Reinaldo Vega, Mahopac, NY (US); Kisik Choi, Watervliet, NY (US); Ravikumar Ramachandran, Pleasantville, NY (US)

(21) Appl. No.: 18/958,255

(22) Filed: Nov. 25, 2024

(51) Int. Cl. H01L 29/417; H01L 29/06; H01L 29/423; H01L 29/775; H01L 29/786

(52) U.S. Cl. CPC H10D 30/6729; H10D 30/43; H10D 30/6735; H10D 30/6757; H10D 62/121

(57) ABSTRACT

A semiconductor structure including a dielectric bar arranged between and physically separating a first source drain region from a second source drain region, where a height of the first source drain region is less than a height of the second source drain region, and a backside source drain contact directly beneath and in electrical communication with the second source drain region.

### BACKGROUND

The present invention generally relates to semiconductor structures, and more particularly to fork sheet device structures having direct backside contacts with tight cell boundaries.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a dielectric bar arranged between and physically separating a first source drain region from a second source drain region, where a height of the first source drain region is less than a height of the second source drain region, and a backside source drain contact directly beneath and in electrical communication with the second source drain region.

According to another embodiment of the present invention, a semiconductor structure is provided. The semiconductor structure may include a dielectric bar arranged between and physically separating a first source drain region from a second source drain region, where a height of the first source drain region is less than a height of the second source drain region, and a backside source drain contact directly beneath and in electrical communication with the second source drain region, where a top surface of the backside source drain contact is in direct contact with a bottom surface of the dielectric bar.

According to another embodiment of the present invention, a semiconductor structure is provided. The semiconductor structure may include a dielectric bar arranged vertically and physically separating a first source drain region from a second source drain region, where a vertical height of the first source drain region is less than a vertical height of the second source drain region, a backside source drain contact directly beneath and in electrical communication with the second source drain region, a semiconductor layer in direct contact with sidewalls of the second source drain region and sidewalls of the backside source drain contact, and a backside dielectric layer between and physically separating the first source drain region from the backside source drain contact.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of a semiconductor structure after forming a middle-of-line, a back-end-of-line, a carrier wafer according to an exemplary embodiment;

FIGS. 8, 9, and 10 are cross-sectional views of the semiconductor structure flipping the assembly and recessing the substrate according to an exemplary embodiment;

FIGS. 11, 12, and 13 are cross-sectional views of the semiconductor structure forming first backside contact structures and second backside contact structures according to an exemplary embodiment;

FIGS. 14, 15, and 16 are cross-sectional views of the semiconductor structure anisotropically recessing the top semiconductor layer according to an exemplary embodiment;

FIGS. 17, 18, and 19 are cross-sectional views of the semiconductor structure isotropically recessing the top semiconductor layer according to an exemplary embodiment; and

FIGS. 20, 21, and 22 are cross-sectional views of the semiconductor structure forming a backside dielectric layer and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As semiconductor devices continue to decrease in size, it has become desirable to provide distances between the near-most nFET and pFET active regions (i.e., the “N2P space”). Providing N2P spaces at these dimensions can present challenges to communicating with the pFET section and the nFET section. Specifically, N2P spaces on this order reduce the process window within which contact structures connecting the nFET section and pFET section could electrically short with one another. Although the process window can be broadened by positioning the contact structures at locations laterally offset from the N2P space, doing so increases the electrical resistance between the contact structures and the respective pFET section and nFET section, thereby offsetting any improvement in process window and/or electrical characteristics of the multilayer IC device.

The trend to continue reducing the footprint of FET devices has led to the development of forked nanosheet semiconductor devices, also referred to as “fork sheet devices.” A fork sheet device implements nanosheets that are controlled by a tri-gate forked structure. The tri-gate forked structure is realized by forming a dielectric bar or dielectric wall between the P-type and N-type devices. The dielectric bar physically isolates the two adjacent devices from one another, allowing much tighter N2P spacing that facilitates superior area and performance scalability compared to traditional nanosheet devices. However, the scalability achieved by fork sheet devices along with the introduction of the dielectric bar makes it difficult to maximize the source/drain contact area.

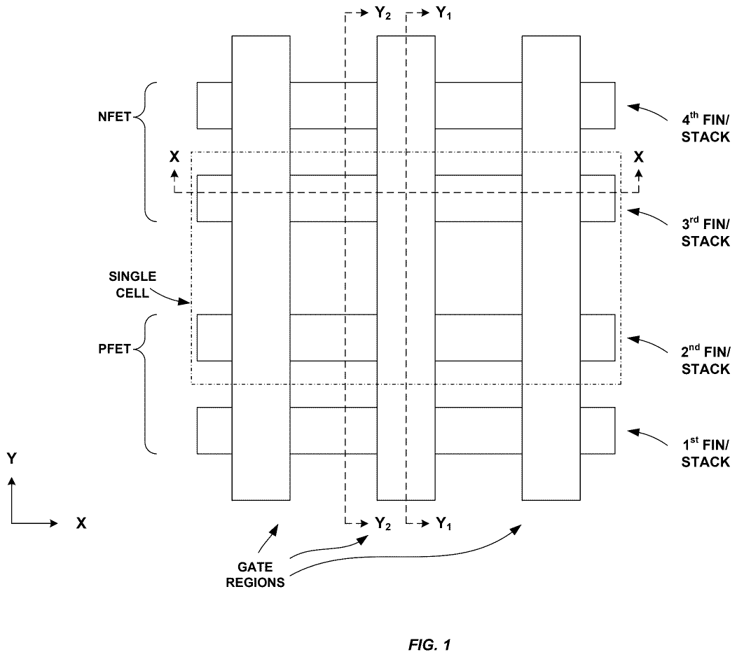

The present invention generally relates to semiconductor structures, and more particularly to fork sheet device structures having direct backside contacts with tight cell boundaries. More specifically, the fork sheet device structures, and associated method disclosed herein enable a novel solution for providing direct backside contacts at very tight N2N space and PSP space without patterning issues or contact-to-contact shorting. The fork sheet devices of the disclosed embodiments, include a dielectric bar or dielectric wall between at the cell boundary and between adjacent source drain regions of the same type. Exemplary embodiments of fork sheet device structures having direct backside contacts with tight cell boundaries are described in detail below by referring to the accompanying drawings in FIGS. 1 to 22. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, a third fin/stack, a fourth fin/stack, and gate regions situated perpendicular to the fins/stacks. FIGS. 1-22 represent cross section views oriented as indicated in FIG. 1

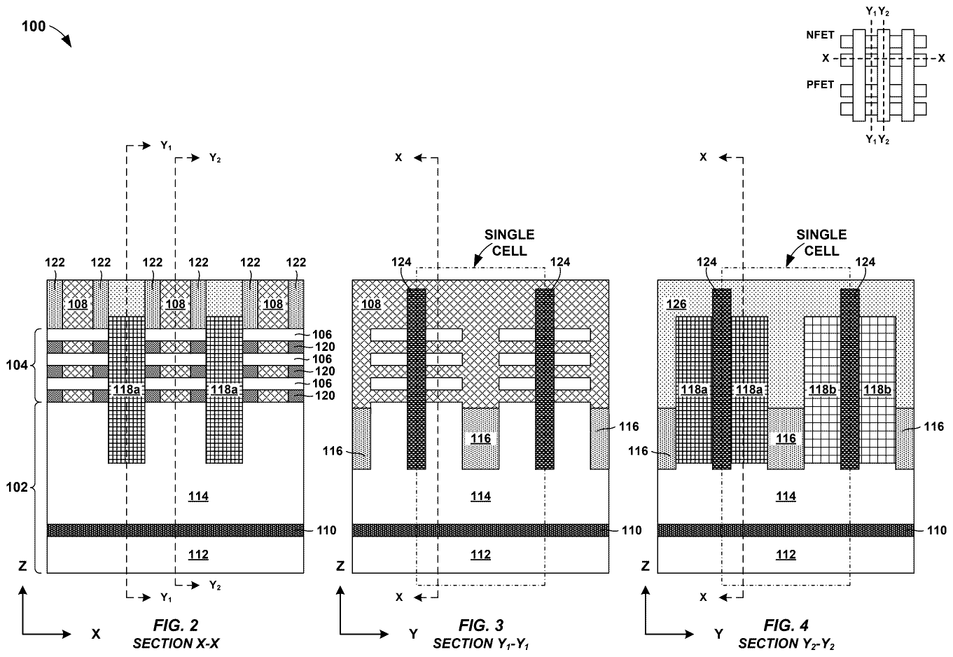

Referring now to FIGS. 2, 3, and 4, a structure 100 is shown during an intermediate step of a method of fabricating a nanosheet transistor structure according to an embodiment of the invention. FIG. 2 depicts a cross-sectional view of the structure 100 taken along line X-X, FIG. 3 depicts a cross-sectional view of the structure 100 taken along line Y₁-Y₁, and FIG. 4 depicts a cross-sectional view of the structure 100 taken along line Y₂-Y₂.

The structure 100 illustrated in FIGS. 2-4 includes an array of fork sheet devices formed on a substrate 102 in accordance with known techniques. As illustrated, the array of nanosheet transistors includes nanosheet stacks 104. Each nanosheet stack 104 includes a plurality of nanosheet channels 106 surrounded by a gate structure 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes shallow trench isolation regions 116 (hereinafter “STI regions 116”), first source drain regions 118a, second source drain regions 118b, inner spacers 120, and gate spacers 122, dielectric bars 124, and a dielectric layer 126.

The STI regions 116 extend partially into the substrate 102 below the array of fork sheet devices. In general, the STI regions 116 may each include an isolation liner (not shown) and an isolation fill (not shown). For example, the isolation liner is SiN, SiON, or SiOCN, and the isolation fill is silicon oxide (SiO) or silicon nitride (SiN).

The first and second source drain regions 118a, 118b are formed between adjacent nanosheet stacks 104 in direct contact with exposed ends of the nanosheet channels 106 according to known techniques. More specifically, the first and second source drain regions 118a, 118b may be epitaxially grown from the exposed ends of the nanosheet channels 106 according to known techniques. Typically, in-situ doping is used to dope the first and second source drain regions 118a, 118b, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, the first source drain regions 118a are a first-type, for example, P-type, and the second source drain regions 118b are a second-type, for example, N-type, as illustrated in FIGS. 2-4. Said differently, according to the disclosed embodiments, the first source drain regions 118a are both the same type, for example, P-type, and the second source drain regions 118b are both the same type, for example, N-type. Additional embodiment explicitly contemplate different variations or combinations of N-type and P-type source drain regions.

Specific to the disclosed embodiments, the first and second source drain regions 118a, 118b extend into the substrate 102, rather than merely being formed on top or above the substrate 102. Critical to the disclosed embodiments, the first and second source drain regions 118a, 118b shall be formed to a depth below the gate structure 108. Said differently, at this stage of fabrication, bottommost surfaces of the first and second source drain regions 118a, 118b are below bottommost surfaces of the gate structures 108, as illustrated. Doing so is enables a backside contact scheme to allow for tighter gate pitch without risking the backside contacts shorting to bottoms of the gate. Additionally, it is noted that sidewalls of the STI regions 116 are in direct contact with sidewalls of the first and second source drain regions 118a, 118b, as illustrated.

The inner spacers 120 are disposed between the nanosheet channels 106, and laterally separate the gate structures 108 from the first and second source drain regions 118a, 118b, as illustrated. The inner spacers 120 provide necessary electrical insulation between the gate structures 108 and the first and second source drain regions 118a, 118b according to known techniques.

The gate spacers 122 are provided to define the channel length and the source drain regions, and ultimately electrically insulate the gate structures 108 from subsequently formed structures, such as, for example, source drain contact structures. The gate spacers 122 are critical for electrically insulating the gate structures 108 from the first and second source drain regions 118a, 118b or subsequently formed contact structures. In at least one embodiment, the gate spacers 122 include silicon nitride, silicon boron nitride, silicon carbon nitride, silicon boron carbon nitride, or other known equivalents.

The dielectric bars 124 are provided to bifurcate or divide device regions to create more devices in a smaller footprint. Specifically, according to the disclosed embodiments the dielectric bars 124 bifurcate or divide nanosheet stacks and source drain regions formed at a pitch limited by current lithography, into discrete devices having smaller a pitch smaller than possible with current lithography. For example, the nanosheet stacks and source drain regions prior to formation of the dielectric bars 124 have a lateral width, measured in the y-direction, of approximately of 40 nm, and adding the dielectric bars 124 will bifurcate the nanosheet stacks and source drain regions into two smaller structures, each having a lateral width less than 20 nm. Further, the dielectric bars 124 of the disclosed embodiments have a lateral width, measured in a y-direction, less than a lateral width of the STI regions 116. In doing so,

Said differently, the N2N spacing between the first source drain regions 118a and the P2P spacing between the second source drain regions 118b is dictated by the lateral width of the dielectric bars 124.

Additionally, a single cell extends in the y-direction from one gate cut structures to another dielectric bar, as illustrated by the dotted line in the figure. According to the illustrated embodiment, the single cell includes one or more PFET devices and one or more NFET devices. In other embodiments, the single cell includes only PFET devices or only NFET devices.

The dielectric bars 124 are formed according to known techniques and as illustrated. The dielectric bars 124 are formed at the cell boundary and bifurcate what previously was a single nanosheet stack into two adjacent nanosheet stacks 104, as illustrated in FIG. 3. Similarly, the dielectric bars 124 also bifurcate what previously was single source drain regions two adjacent source drain regions, as illustrated in FIG. 4. According to the disclosed embodiments, topmost surfaces of the dielectric bars 124 are above topmost surfaces of the first and second source drain regions 118a, 118b.

According to the embodiments disclosed herein, individual gate regions defined by the dielectric bars 124 may include a single nanosheet stack 104 or multiple nanosheet stacks 104 having a common gate structure. Additionally, the different nanosheet stacks 104 separated by the dielectric bars 124 may be N-type, P-type, or any combination thereof. Finally, the dielectric bars 124 can be positioned anywhere according to a desired design, and are not necessarily limited to the positions and configurations depicted and described herein.

Finally, the structure 100 further includes the dielectric layer 126 directly above and surrounding the first and second source drain regions 118a, 118b. The dielectric layer 126 is composed of any suitable interlayer dielectric material, such as, for example, oxides such as silicon oxide (SiOₓ), nitrides such as silicon nitride (SiₓN_{y}), and/or low-k materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 126. Using a self-planarizing dielectric material as the dielectric layer 126 can avoid the need to perform a subsequent planarizing step. After formation, top surfaces of the dielectric layer 126 are typically made flush, or substantially flush, with top surfaces of the gate structures 108 and gate spacers 122 by chemical mechanical polishing techniques.

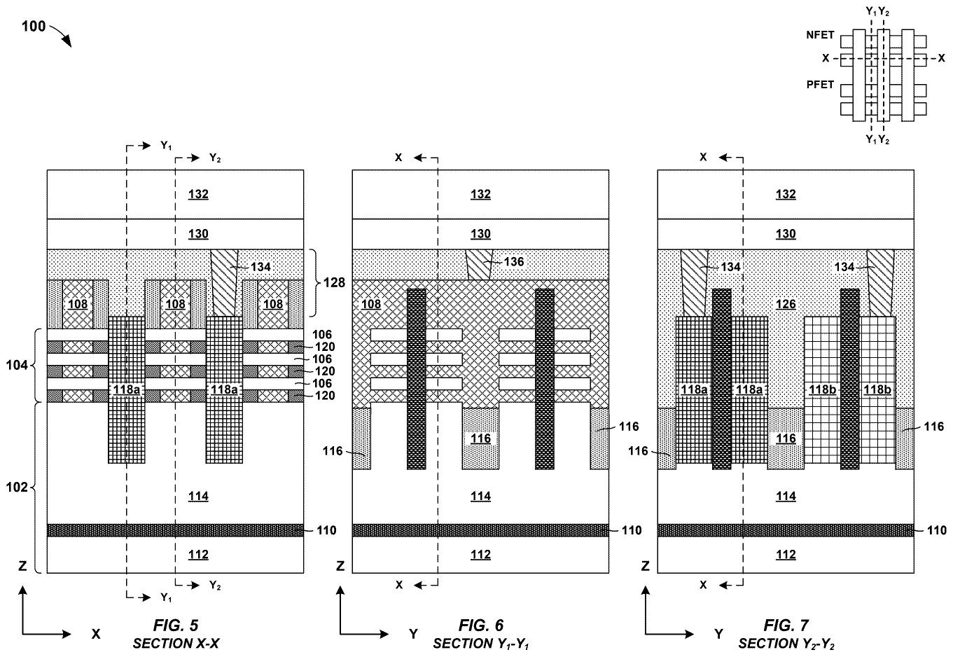

Referring now to FIGS. 5, 6, and 7, a structure 100 is shown after forming a middle-of-line 128, a back-end-of-line 130, a carrier wafer 132 according to an embodiment of the invention. FIG. 5 depicts a cross-sectional view of the structure 100 taken along line X-X, FIG. 6 depicts a cross-sectional view of the structure 100 taken along line Y₁-Y₁, and FIG. 7 depicts a cross-sectional view of the structure 100 taken along line Y₂-Y₂.

The middle-of-line 128 includes source drain contacts 134 and gate contacts 136 which may be generally referred to as middle-of-line contacts. The source drain contacts 134 and the gate contacts 136 are formed according to known techniques. The back-end-of-line 130 may include vias and metal lines which may be generally referred to as back-end-of-line interconnects. The vias and the metal lines are formed according to known techniques. Finally, the carrier wafer 132 is secured to a top of the structure 100 according to an embodiment of the invention. The carrier wafer 132 is attached, or removably secured, to the back-end-of-line 130. In general, and not depicted, the carrier wafer 132 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 132 according to known techniques.

Although only a limited number of components, devices, or structures are shown, embodiments of the present invention shall not be limited by any quantity otherwise illustrated or discussed herein.

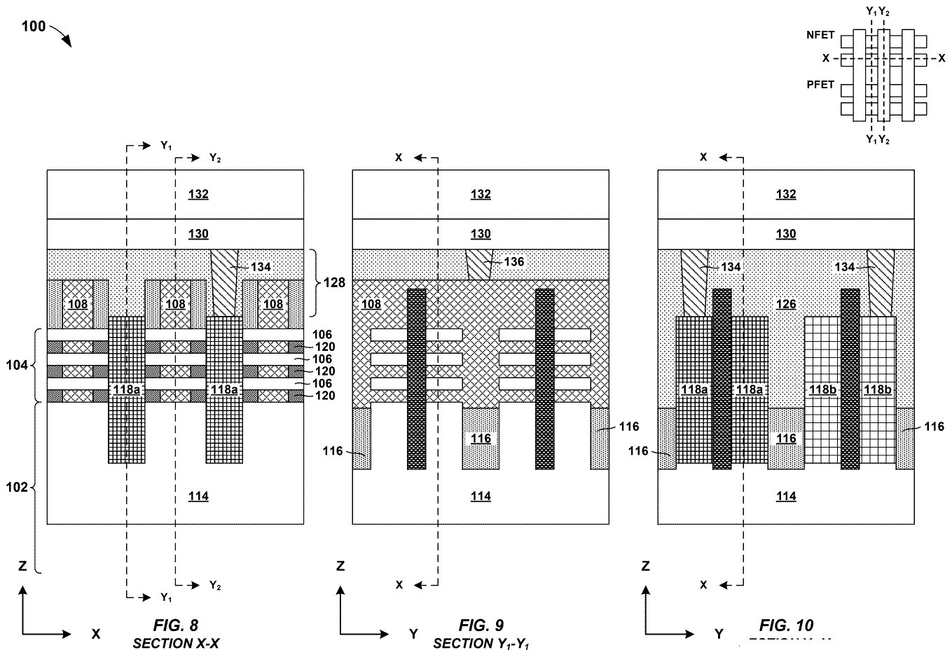

Referring now to FIGS. 8, 9, and 10, a structure 100 is shown after flipping the assembly and recessing the substrate 102 according to an embodiment of the invention. FIG. 8 depicts a cross-sectional view of the structure 100 taken along line X-X, FIG. 9 depicts a cross-sectional view of the structure 100 taken along line Y₁-Y₁, and FIG. 10 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 and the etch stop layer 110 are recessed and completely removed to expose the top semiconductor layer 114, as shown.

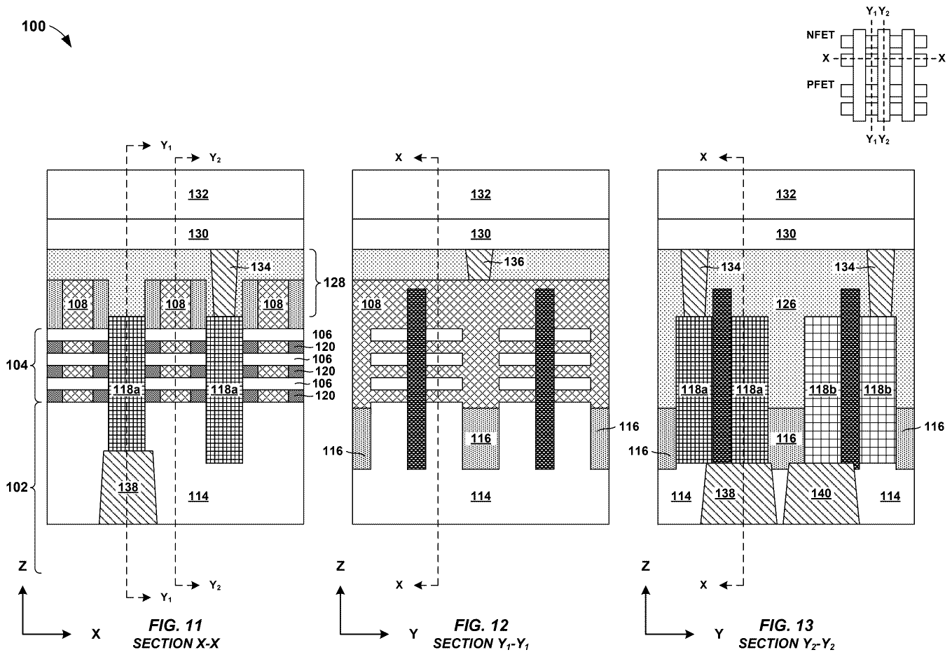

Referring now to FIGS. 11, 12, and 13, a structure 100 is shown after forming first backside contact structures 138 and second backside contact structures 140 according to an embodiment of the invention. FIG. 11 depicts a cross-sectional view of the structure 100 taken along line X-X, FIG. 12 depicts a cross-sectional view of the structure 100 taken along line Y₁-Y₁, and FIG. 13 depicts a cross-sectional view of the structure 100 taken along line Y₂-Y₂.

First, a mask (not shown) is deposited and subsequently patterned to expose certain portions of the structure 100 according to known techniques. The mask can be an organic planarization layer (OPL) or a layer of material that is capable of being planarized or etched by known techniques. In an embodiment, for example, the mask can be an amorphous carbon layer able to withstand subsequent processing temperatures. The mask can preferably have a thickness sufficient to cover existing structures. After depositing the mask, a dry etching technique is applied to pattern or recess the mask according to known techniques. The mask is patterned consistent with a size and a location of the first and second backside contact structures 138, 140. For example, after patterning the mask, portions of the structure 100 in contact regions are exposed.

Next, exposed portions of the top semiconductor layer 114 are removed to form backside contact trenches (not show) according to known techniques. Specifically, exposed portions of the top semiconductor layer 114 are removed using known etching techniques suitable to remove silicon substrate materials selective to the mask, the STI regions 116 and the first and second source drain regions 118a, 118b. In an embodiment, the exposed portions of the top semiconductor layer 114 are removed using an anisotropic etch such as, for example, reactive ion etching. After removing the exposed portions of the top semiconductor layer 114, bottom surfaces of the first and the second source drain regions 118a, 118b are exposed at tops of the backside contact trenches.

Next, the backside contact trenches are filled with a conductive material to form the first and second backside contact structures 138, 140 according to known techniques. The first and second backside contact structures 138, 140 may include any suitable conductive material, such as, for example, copper, ruthenium, aluminum, tungsten, cobalt, or alloys thereof. In some embodiments, a metal silicide is formed at the bottom of the backside contact trenches prior to filling them with the conductive material.

After deposition, excess conductive material can be polished using known techniques until bottommost surfaces of the first and second backside contact structures 138, 140 are flush, or substantially flush, with bottommost surfaces of the top semiconductor layer 114, as illustrated. After polishing, bottommost surfaces of the first and second backside contact structures 138, 140 are substantially flat. It is noted, the first and second backside contact structures 138, 140 may include, for example, backside source drain contacts, as illustrated. It is noted, according to the disclosed embodiments, the first and second backside contact structures 138, 140 are arranged to target one source drain region on either side of the dielectric bar 124, rathe than both. For example, with reference to FIG. 13, the first backside contact structure 138 is targeted to provide an electrical connection to the first source drain regions 118a on the right of one of the dielectric bar (124), and the second backside source drain contact structure 140 is targeted to provide an electrical connection to the second source drain regions 118b on the left of another dielectric bar (124). In the disclose embodiment, the first and second backside contact structures 138, 140 also directly contact bottoms, specifically bottom surfaces, of the dielectric bars 124. Due to very small N2N spacing and P2P spacing, the first and second backside contact structures 138, 140 can easily short to neighboring source drain regions. To that end, the first backside source drain contact structure 138 is vertically aligned the first source drain regions 118a on the right of one of the dielectric bar (124), and the second backside source drain contact structure 140 is vertically aligned with the second source drain regions 118b on the left of another dielectric bar (124).

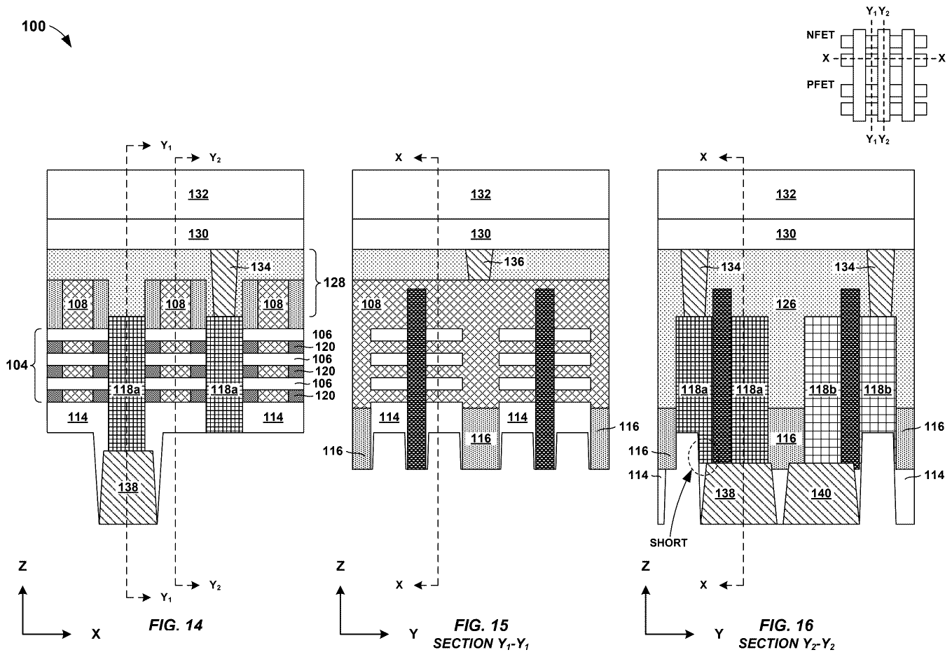

Referring now to FIGS. 14, 15, and 16, a structure 100 is shown after anisotropically recessing the top semiconductor layer 114 according to an embodiment of the invention. FIG. 14 depicts a cross-sectional view of the structure 100 taken along line X-X, FIG. 15 depicts a cross-sectional view of the structure 100 taken along line Y₁-Y₁, and FIG. 16 depicts a cross-sectional view of the structure 100 taken along line Y₂-Y₂.

The mask is removed and remaining portions of the top semiconductor layer 114 are anisotropically recessed according to known techniques. Specifically, the top semiconductor layer 114 is recessed selective to the STI regions 116, the dielectric bars 124, and the first and second backside contact structures 138, 140. In an embodiment, the top semiconductor layer 114 is recessed using an anisotropic etch such as, for example, reactive ion etching. After recessing the top semiconductor layer 114, bottom surfaces of the first and the second source drain regions 118a, 118b are exposed, and some recessed. It is noted, the possibility of a short between the first and second backside contact structures 138, 140 and neighboring source drain regions remains due to tight N2N or P2P spacing, as noted in FIG. 16.

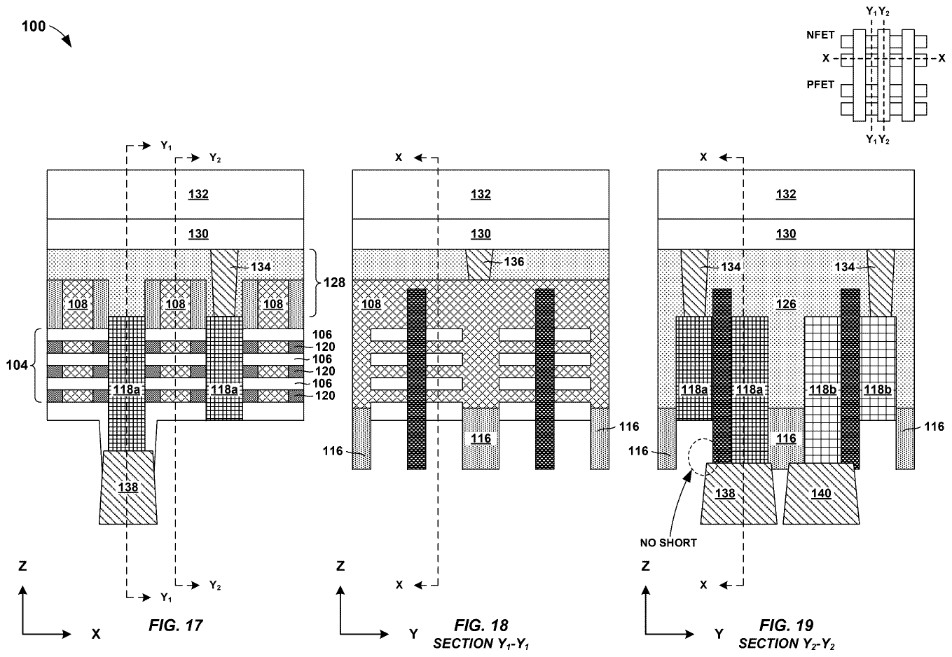

Referring now to FIGS. 17, 18, and 19, a structure 100 is shown after isotropically recessing the top semiconductor layer 114 according to an embodiment of the invention. FIG. 17 depicts a cross-sectional view of the structure 100 taken along line X-X, FIG. 18 depicts a cross-sectional view of the structure 100 taken along line Y₁-Y₁, and FIG. 19 depicts a cross-sectional view of the structure 100 taken along line Y₂-Y₂.

The remaining portions of the top semiconductor layer 114 are isotropically recessed according to known techniques. Specifically, the top semiconductor layer 114 is recessed selective to the STI regions 116, the dielectric bars 124, and the first and second backside contact structures 138, 140, as illustrated. In an embodiment, the top semiconductor layer 114 is recessed using an etch process such as, for example, wet etch.

During recessing of the top semiconductor layer 114, bottom surfaces of the first and the second source drain regions 118a, 118b are also recessed, as illustrated. After recessing, the possibility of a short between the first and second backside contact structures 138, 140 and neighboring source drain regions is eliminated, and presence of the dielectric bars 124 prevents lateral damage to neighboring source drain regions, as noted in FIG. 19.

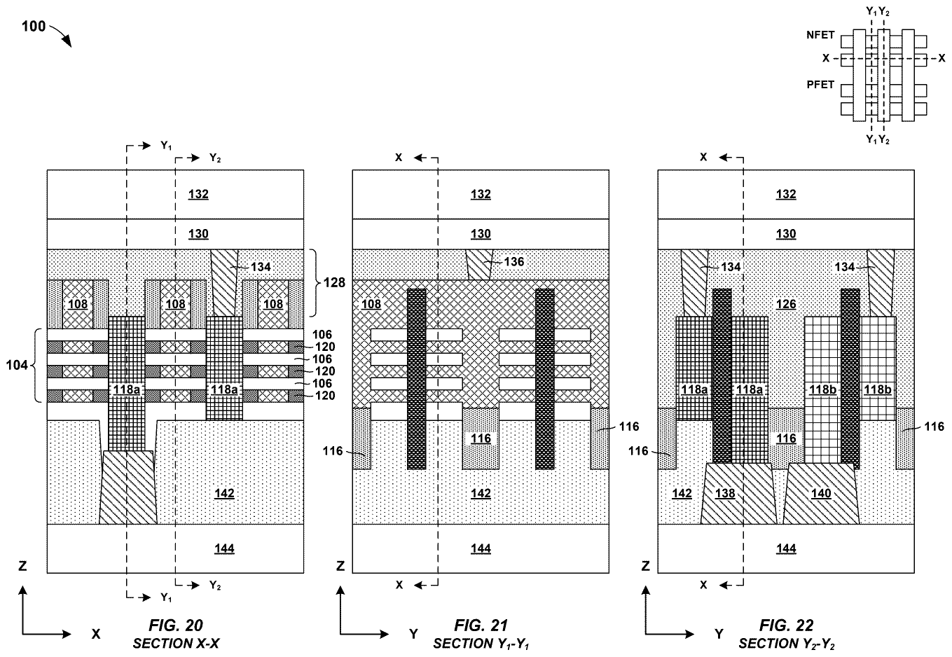

Referring now to FIGS. 20, 21, and 22, a structure 100 is shown after forming a backside dielectric layer 142 and backside wiring layers 144 according to an embodiment of the invention. FIG. 20 depicts a cross-sectional view of the structure 100 taken along line X-X, FIG. 21 depicts a cross-sectional view of the structure 100 taken along line Y₁-Y₁, and FIG. 22 depicts a cross-sectional view of the structure 100 taken along line Y₂-Y₂.

The backside dielectric layer 142 is formed by blanket depositing an interlayer dielectric material over the backside of the structure 100 according to known techniques. Specifically, the backside dielectric layer 142 is formed on remaining portions of the top semiconductor layer 114, exposed surfaces of the source drain regions 118a, 118b, and between the STI regions 116 and the dielectric bars 124, as illustrated.

The backside dielectric layer 142 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 142. Using a self-planarizing dielectric material as the backside dielectric layer 142 can avoid the need to perform a subsequent planarizing step.

After forming the backside dielectric layer 142, the backside wiring layers 144 are subsequently formed according to known techniques. The backside wiring layers 144 typically include at least backside power rails and a backside power delivery network.

According to the embodiment illustrated in FIGS. FIGS. 20-22, the transistor structures represented by the structure 100 have some distinctive notable features. For instance, the dielectric bars 124 are arranged between and physically separates the first source drain regions 118a from one another (FIG. 22). Similarly, the dielectric bars 124 are arranged between and physically separates the second source drain regions 118b from one another (FIG. 22). Of note, a height of one of the first source drain regions 118a (left) is less than a height of another one of the first source drain regions 118a (right), as best illustrated in FIG. 22. Further, one of the first backside contact structures 138 is directly beneath and in electrical communication with one of the first source drain regions 118a (right), as best illustrated in FIG. 22. Even further, a top surface of one of the first backside contact structures 138 is in direct contact with a bottom surface of the dielectric bar 124.

Another distinguishable feature of the structure 100 is portions of the top semiconductor layer 114 remain in direct contact with sidewalls of the first source drain regions 118a as well as sidewalls of the backside contact structures 138, as best illustrated in FIG. 20. Moreover, the backside dielectric layer 142 is present between, and physically separates, the first source drain regions 118a from the backside contact structures 138. the structure 100 further includes a frontside source drain contact 134 directly above and in electrical communication with the first source drain regions 118a (left, FIG. 22). The structure 100 further includes a STI region 116, wherein a sidewall of the STI region 116 is in direct contact with a sidewall of the first source drain regions 118a (right, FIG. 22).

Additionally, a bottom surface of the dielectric bar 124 is substantially flush with a bottom surface of the first source drain regions 118a (right, FIG. 22), and, a bottom surface of the first source drain regions 118a (right, FIG. 22) is lower than a bottom surface of a gate structure 108.

Moreover, the first source drain regions 118a (left, FIG. 22) and the first source drain regions 118a (right, FIG. 22) are of a same type. Further yet, a portion of the backside contact structures 138 extend laterally beneath the first source drain regions 118a (left, FIG. 22), and wherein the backside contact structures 138 are physically separated from the first source drain regions 118a (left, FIG. 22) by a backside dielectric layer.

With continued reference to FIGS. 20-22, and according to an embodiment, the structure 100 includes a dielectric bar arranged between and physically separating a first source drain region from a second source drain region, where a height of the first source drain region is less than a height of the second source drain region, and a backside source drain contact directly beneath and in electrical communication with the second source drain region.

With continued reference to FIGS. 20-22, and according to an embodiment, the structure further includes a frontside source drain contact directly above and in electrical communication with the first source drain region.

With continued reference to FIGS. 20-22, and according to an embodiment, the structure further includes a shallow trench isolation region, wherein a sidewall of the shallow trench isolation region is in direct contact with a sidewall of the second source drain region.

With continued reference to FIGS. 20-22, and according to an embodiment, a bottom surface of the dielectric bar is substantially flush with a bottom surface of the second source drain region.

With continued reference to FIGS. 20-22, and according to an embodiment, a bottom surface of the second source drain region is lower than a bottom surface of a gate structure.

With continued reference to FIGS. 20-22, and according to an embodiment, the first source drain region and the second source drain region are of a same type.

With continued reference to FIGS. 20-22, and according to an embodiment, a portion of the backside source drain contact extends laterally beneath the first source drain region, and wherein the backside source drain contact is physically separated from the first source drain region by a backside dielectric layer

With continued reference to FIGS. 20-22, and according to an embodiment, the structure 100 includes a dielectric bar arranged between and physically separating a first source drain region from a second source drain region, where a height of the first source drain region is less than a height of the second source drain region, and a backside source drain contact directly beneath and in electrical communication with the second source drain region, where a top surface of the backside source drain contact is in direct contact with a bottom surface of the dielectric bar.

With continued reference to FIGS. 20-22, and according to an embodiment, the structure 100 includes a dielectric bar arranged vertically and physically separating a first source drain region from a second source drain region, where a vertical height of the first source drain region is less than a vertical height of the second source drain region, a backside source drain contact directly beneath and in electrical communication with the second source drain region, a semiconductor layer in direct contact with sidewalls of the second source drain region and sidewalls of the backside source drain contact, and a backside dielectric layer between and physically separating the first source drain region from the backside source drain contact.

Various examples may possibly be described by one or more of the following features in the following numbered clauses:
Clause 1: A semiconductor structure comprising: a dielectric bar arranged between and physically separating a first source drain region from a second source drain region, wherein a height of the first source drain region is less than a height of the second source drain region; and a backside source drain contact directly beneath and in electrical communication with the second source drain region.
Clause 2: The semiconductor structure according to clause 1, further comprising: a frontside source drain contact directly above and in electrical communication with the first source drain region.
Clause 3: The semiconductor structure according to clause 1 or 2, further comprising: a shallow trench isolation region, wherein a sidewall of the shallow trench isolation region is in direct contact with a sidewall of the second source drain region.
Clause 4: The semiconductor structure according to clause 1, 2, or 3, wherein a bottom surface of the dielectric bar is substantially flush with a bottom surface of the second source drain region.
Clause 5: The semiconductor structure according to clause 1, 2, 3, or 4, wherein a bottom surface of the second source drain region is lower than a bottom surface of a gate structure.
Clause 6: The semiconductor structure according to clause 1, 2, 3, 4, or 5, wherein the first source drain region and the second source drain region are of a same type.
Clause 7: The semiconductor structure according to clause 1, 2, 3, 4, 5, or 6, wherein a portion of the backside source drain contact extends laterally beneath the first source drain region, and wherein the backside source drain contact is physically separated from the first source drain region by a backside dielectric layer.
Clause 8: A semiconductor structure comprising: a dielectric bar arranged between and physically separating a first source drain region from a second source drain region, wherein a height of the first source drain region is less than a height of the second source drain region; and a backside source drain contact directly beneath and in electrical communication with the second source drain region, wherein a top surface of the backside source drain contact is in direct contact with a bottom surface of the dielectric bar.
Clause 9: The semiconductor structure according to claim 8, further comprising: a frontside source drain contact directly above and in electrical communication with the first source drain region.
Clause 10: The semiconductor structure according to clause 8 or 9, further comprising: a shallow trench isolation region, wherein a sidewall of the shallow trench isolation region is in direct contact with a sidewall of the second source drain region.
Clause 11: The semiconductor structure according to clause 8, 9, or 10, wherein the bottom surface of the dielectric bar is substantially flush with a bottom surface of the second source drain region.
Clause 12: The semiconductor structure according to clause 8, 9, 10, or 11, wherein a bottom surface of the second source drain region is lower than a bottom surface of a gate structure.
Clause 13: The semiconductor structure according to clause 8, 9, 10, 11, or 12, wherein the first source drain region and the second source drain region are of a same type.
Clause 14: The semiconductor structure according to clause 8, 9, 10, 11, 12, or 13, wherein a portion of the backside source drain contact extends laterally beneath the first source drain region, and wherein the backside source drain contact is physically separated from the first source drain region by a backside dielectric layer.
Clause 14: A semiconductor structure comprising: a dielectric bar arranged vertically and physically separating a first source drain region from a second source drain region, wherein a vertical height of the first source drain region is less than a vertical height of the second source drain region; a backside source drain contact directly beneath and in electrical communication with the second source drain region; a semiconductor layer in direct contact with sidewalls of the second source drain region and sidewalls of the backside source drain contact; and a backside dielectric layer between and physically separating the first source drain region from the backside source drain contact.
Clause 16: The semiconductor structure according to claim 15, further comprising: a frontside source drain contact directly above and in electrical communication with the first source drain region.
Clause 17: The semiconductor structure according to clause 15 or 16, further comprising: a shallow trench isolation region, wherein a sidewall of the shallow trench isolation region is in direct contact with a sidewall of the second source drain region.
Clause 18: The semiconductor structure according to clause 15, 16, or 17, wherein a bottom surface of the dielectric bar is substantially flush with a bottom surface of the second source drain region.
Clause 19: The semiconductor structure according to clause 15, 16, 17, or 18, wherein a bottom surface of the second source drain region is lower than a bottom surface of a gate structure.
Clause 20: The semiconductor structure according to clause 15, 16, 17, 18, and 19, wherein the first source drain region and the second source drain region are of a same type.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a dielectric bar arranged between and physically separating a first source drain region from a second source drain region, wherein a height of the first source drain region is less than a height of the second source drain region; and
a backside source drain contact directly beneath and in electrical communication with the second source drain region.

2. The semiconductor structure according to claim 1, further comprising:
a frontside source drain contact directly above and in electrical communication with the first source drain region.

3. The semiconductor structure according to claim 1, further comprising:
a shallow trench isolation region, wherein a sidewall of the shallow trench isolation region is in direct contact with a sidewall of the second source drain region.

4. The semiconductor structure according to claim 1, wherein a bottom surface of the dielectric bar is substantially flush with a bottom surface of the second source drain region.

5. The semiconductor structure according to claim 1, wherein a bottom surface of the second source drain region is lower than a bottom surface of a gate structure.

6. The semiconductor structure according to claim 1, wherein the first source drain region and the second source drain region are of a same type.

7. The semiconductor structure according to claim 1, wherein a portion of the backside source drain contact extends laterally beneath the first source drain region, and wherein the backside source drain contact is physically separated from the first source drain region by a backside dielectric layer.

8. A semiconductor structure comprising:
a dielectric bar arranged between and physically separating a first source drain region from a second source drain region, wherein a height of the first source drain region is less than a height of the second source drain region; and
a backside source drain contact directly beneath and in electrical communication with the second source drain region, wherein a top surface of the backside source drain contact is in direct contact with a bottom surface of the dielectric bar.

9. The semiconductor structure according to claim 8, further comprising:
a frontside source drain contact directly above and in electrical communication with the first source drain region.

10. The semiconductor structure according to claim 8, further comprising:
a shallow trench isolation region, wherein a sidewall of the shallow trench isolation region is in direct contact with a sidewall of the second source drain region.

11. The semiconductor structure according to claim 8, wherein the bottom surface of the dielectric bar is substantially flush with a bottom surface of the second source drain region.

12. The semiconductor structure according to claim 8, wherein a bottom surface of the second source drain region is lower than a bottom surface of a gate structure.

13. The semiconductor structure according to claim 8, wherein the first source drain region and the second source drain region are of a same type.

14. The semiconductor structure according to claim 8, wherein a portion of the backside source drain contact extends laterally beneath the first source drain region, and wherein the backside source drain contact is physically separated from the first source drain region by a backside dielectric layer.

15. A semiconductor structure comprising:
a dielectric bar arranged vertically and physically separating a first source drain region from a second source drain region, wherein a vertical height of the first source drain region is less than a vertical height of the second source drain region;
a backside source drain contact directly beneath and in electrical communication with the second source drain region;
a semiconductor layer in direct contact with sidewalls of the second source drain region and sidewalls of the backside source drain contact; and
a backside dielectric layer between and physically separating the first source drain region from the backside source drain contact.

16. The semiconductor structure according to claim 15, further comprising:
a frontside source drain contact directly above and in electrical communication with the first source drain region.

17. The semiconductor structure according to claim 15, further comprising:
a shallow trench isolation region, wherein a sidewall of the shallow trench isolation region is in direct contact with a sidewall of the second source drain region.

18. The semiconductor structure according to claim 15, wherein a bottom surface of the dielectric bar is substantially flush with a bottom surface of the second source drain region.

19. The semiconductor structure according to claim 15, wherein a bottom surface of the second source drain region is lower than a bottom surface of a gate structure.

20. The semiconductor structure according to claim 15, wherein the first source drain region and the second source drain region are of a same type.
